(19) United States
(12) Patent Application Publication
(10) Pub. No.: US 2026/0205003 A1
(43) Pub. Date: Jul. 16, 2026

(54) CONTROL CIRCUIT, SWITCHED-CAPACITOR CONVERTER, CHIP, AND ELECTRONIC DEVICE

(71) Applicant: Zhuhai Nanxin Semiconductor Technology Co., Ltd., Zhuhai (CN)

(72) Inventors: Xiang Zhou, Zhuhai (CN); Wei Zhao, Zhuhai (CN)

(73) Assignee: Zhuhai Nanxin Semiconductor Technology Co., Ltd., Zhuhai (CN)

(21) Appl. No.: 19/387,692

(22) Filed: Nov. 13, 2025

(30) Foreign Application Priority Data
Nov. 13, 2024 (CN) 202411623211.0

(51) Int. Cl. H02M 1/08; H02M 3/07; H03K 17/082; H03K 19/0185

(52) U.S. Cl. CPC H02M 1/08; H02M 3/07; H03K 17/0822; H03K 19/018571

(57) ABSTRACT

Provided are a control circuit, a switched-capacitor converter, a chip, and an electronic device. The control circuit includes: a control voltage output circuit and a level shifter circuit. The control voltage output circuit may acquire the control voltage based on the reference voltage and the feedback voltage, and transmit the control voltage to the level shifter circuit, such that the level shifter circuit acquires the control voltage. Hence, the control circuit may control the turn-on voltage of the first power transistor by using the control voltage, to control the input current or the output current or the output voltage. Consequently, the impedance of the switched-capacitor converter is changed. This prevents overvoltage and overcurrent issues or other hazardous operating conditions from occurring in a case where the switched-capacitor converter is in an abnormal operating state.

### CROSS REFERENCE TO THE RELATED APPLICATIONS

This application is based upon and claims priority to Chinese Patent Application No. 202411623211.0, filed on Nov. 13, 2024, the entire contents of which are incorporated herein by reference.

### TECHNICAL FIELD

The present disclosure relates to the technical field of power management chips, and in particular, relates to a hybrid buck converter, a chip, and an electronic device.

### BACKGROUND

A switched-capacitor converter, also known as a charge pump, may convert an input voltage into a first output voltage and a second output voltage to satisfy load requirements. Switched-capacitor converters are commonly used in high-power charging applications. Therefore, it is often necessary to limit an input current or an output current or an output voltage of the switched-capacitor converter. Otherwise, under abnormal operating conditions, the switched-capacitor converter is susceptible to overvoltage and overcurrent issues, or to other hazardous operating conditions caused by heat generation. Therefore, in the switched-capacitor converter, it is often necessary to the input current or the output current or the output voltage. Otherwise, the switched-capacitor converter may be prone to overvoltage and overcurrent issues under abnormal operating conditions, or other hazardous operating conditions may occur due to heat generation.

### SUMMARY

The present disclosure provides a control circuit, a switched-capacitor converter, a chip, and an electronic device. The control circuit may control the input current or the output current or the output voltage. This prevents overvoltage and overcurrent issues or other hazardous operating conditions from occurring in a case where the switched-capacitor converter is in an abnormal operating state.

In a first aspect, some embodiments of the present disclosure provide a control circuit, applied in a switched-capacitor converter, wherein the switched-capacitor converter includes: a first power transistor and a first driver circuit. The control circuit includes: a control voltage output circuit and a level shifter circuit.

A first input terminal of the control voltage output circuit is configured to receive a reference voltage, a second input terminal of the control voltage output circuit is configured to receive a feedback voltage, the feedback voltage being used to represent a conversion of an input current or an output current or an output voltage of the switched-capacitor converter, an output terminal of the control voltage output circuit is electrically connected to an input terminal of the level shifter circuit, an output terminal of the level shifter circuit is electrically connected to an input terminal of the first driver circuit, an output terminal of the first driver circuit is electrically connected to a gate of the first power transistor, and a ground terminal of the first driver circuit is electrically connected to a source of the first power transistor.

The control voltage output circuit is configured to, based on the reference voltage and the feedback voltage, acquire a control voltage and transmit the control voltage to the level shifter circuit, wherein the control voltage is used to control an input voltage of the first driver circuit.

The level shifter circuit is configured to shift the control voltage into a voltage domain of the first driver circuit, such that the control circuit controls a turn-on voltage of the first power transistor using the control voltage, to control the input current or the output current or the output voltage.

In the control circuit according to the first aspect, the control voltage output circuit may acquire the control voltage based on the reference voltage and the feedback voltage, and transmit the control voltage to the level shifter circuit, such that the level shifter circuit acquires the control voltage. In this way, the level shifter circuit may shift the control voltage into the voltage domain of the first driver circuit, such that the control voltage is enabled to control the input voltage of the first driver circuit. Hence, the control circuit may control the turn-on voltage of the first power transistor by using the control voltage, to control the input current or the output current or the output voltage. Consequently, the impedance of the switched-capacitor converter is changed. This prevents overvoltage and overcurrent issues or other hazardous operating conditions from occurring in a case where the switched-capacitor converter is in an abnormal operating state.

In some embodiments, the level shifter circuit includes: a current mirror, a voltage-to-current converter circuit, a first transistor, and a first resistor.

An input terminal of the voltage-to-current converter circuit is electrically connected to the output terminal of the control voltage output circuit, an output terminal of the voltage-to-current converter circuit is electrically connected to a source of the first transistor, a gate of the first transistor is configured to receive a control signal, the control signal being used to control turning on or turning off of the first transistor, a drain of the first transistor is electrically connected to an input terminal of the current mirror, an output terminal of the current mirror is electrically connected to a first terminal of the first resistor and the input terminal of the first driver circuit, and a second terminal of the first resistor is electrically connected to the ground terminal of the first driver circuit.

The current mirror is configured to transmit the first current to the first resistor, such that a voltage across the first resistor is the control voltage, and the control voltage is shifted into the voltage domain.

In some embodiments, the voltage-to-current converter circuit includes: a second transistor and a second resistor. A gate of the second transistor is electrically connected to the output terminal of the control voltage output circuit, a drain of the second transistor is electrically connected to the source of the first transistor, a source of the second transistor is electrically connected to a first terminal of the second resistor, and a second terminal of the second resistor is grounded.

In some embodiments, the current mirror includes: a first P-type transistor and a second P-type transistor. A source of the first P-type transistor and a source of the second P-type transistor are both configured to be connected to a first power supply voltage, a gate of the first P-type transistor, a drain of the first P-type transistor, and a gate of the second P-type transistor are all electrically connected to the drain of the first transistor, and a drain of the second P-type transistor is electrically connected to the first terminal of the first resistor.

In some embodiments, the level shifter circuit includes: a charge pump. An input terminal of the charge pump is electrically connected to the output terminal of the control voltage output circuit, and an output terminal of the charge pump is electrically connected to the input terminal of the first driver circuit. The charge pump is configured to, in a first phase, store charge corresponding to the control voltage using a first capacitor in the charge pump, and in a second phase, release the charge stored in the first capacitor, to shift the control voltage into the voltage domain.

In some embodiments, the level shifter circuit further includes: a buffer with a unity gain of 1. A non-inverting input terminal of the buffer is electrically connected to the output terminal of the control voltage output circuit, and an inverting input terminal of the buffer is electrically connected to an output terminal of the buffer and the input terminal of the charge pump. The buffer is configured to perform a unity-gain amplification on the control voltage.

In some embodiments, the charge pump includes: a first switching transistor, a second switching transistor, a third switching transistor, a fourth switching transistor, and a first capacitor.

A first terminal of the first switching transistor is electrically connected to the output terminal of the control voltage output circuit, a second terminal of the first switching transistor is electrically connected to a first terminal of the third switching transistor, a second terminal of the third switching transistor is electrically connected to the input terminal of the first driver circuit, a first terminal of the second switching transistor is grounded, a second terminal of the second switching transistor is electrically connected to a first terminal of the fourth switching transistor, a second terminal of the fourth switching transistor is electrically connected to the ground terminal of the first driver circuit, an upper plate of the first capacitor is electrically connected between the second terminal of the first switching transistor and the first terminal of the third switching transistor, a lower plate of the first capacitor is electrically connected between the second terminal of the second switching transistor and the first terminal of the fourth switching transistor, and a control terminal of the first switching transistor, a control terminal of the second switching transistor, a control terminal of the third switching transistor, and a control terminal of the fourth switching transistor are all configured to receive a control signal, wherein the control signal is used to control turn-on or turn-off of the first switching transistor, the second switching transistor, the third switching transistor, and fourth switching transistor.

In some embodiments, the level shifter circuit includes: a voltage-to-current converter circuit, a current mirror, a first voltage output circuit, and an error amplifier.

A first terminal of the voltage-to-current converter circuit is electrically connected to an input terminal of the current mirror, the input terminal of the first driver circuit, and an output terminal of the error amplifier, a second terminal of the voltage-to-current converter circuit is electrically connected to the ground terminal of the first driver circuit, an output terminal of the current mirror is electrically connected to an input terminal of the first voltage output circuit, an output terminal of the first voltage output circuit is electrically connected to a first input terminal of the error amplifier, and a second input terminal of the error amplifier is electrically connected to the output terminal of the control voltage output circuit.

The voltage-to-current converter circuit is configured to convert the input voltage of the first driver circuit into a first current and transmit the first current to the current mirror.

The current mirror is configured to transmit the first current to the first voltage output circuit.

The first voltage output circuit is configured to, based on the first current, generate a first voltage and transmit the first voltage to the error amplifier, wherein the first voltage is used to represent a variation of the input voltage of the first driver circuit.

The error amplifier is configured to, based on the control voltage and the first voltage, maintain the input voltage of the first driver circuit stable, to shift the control voltage into the voltage domain.

In some embodiments, the level shifter circuit further includes: a sample-and-hold circuit. An input terminal of the sample-and-hold circuit is electrically connected to the output terminal of the first voltage output circuit, and an output terminal of the sample-and-hold circuit is electrically connected to the first input terminal of the error amplifier. The sample-and-hold circuit is configured to, in response to the first power transistor being turned on, sample and hold the first voltage to obtain a second voltage, and transmit the second voltage to the error amplifier, such that the error amplifier, based on the control voltage and the second voltage, maintains the input voltage of the first driver circuit stable.

A first terminal of the fifth switching transistor is electrically connected to the output terminal of the first voltage output circuit, a control terminal of the fifth switching transistor is configured to receive a first control signal, the first control signal being used to control turn-on or turn-off of the fifth switching transistor, a second terminal of the fifth switching transistor is electrically connected to the first input terminal of the error amplifier, an upper plate of the third capacitor is electrically connected between the second terminal of the fifth switching transistor and the first input terminal of the error amplifier, and a lower plate of the third capacitor is grounded.

In some embodiments, the error amplifier includes: a first differential transconductance amplifier, a first P-type transistor, a second P-type transistor, a first transistor, a second transistor, a third transistor, and a fourth transistor.

A source of the first P-type transistor and a source of the second P-type transistor are both configured to be connected to a first power supply voltage, a gate of the first P-type transistor, a drain of the first P-type transistor, and a gate of the second P-type transistor are all electrically connected to a drain of the first transistor, a source of the first transistor is electrically connected to a drain of the second transistor, a drain of the second P-type transistor is electrically connected to a drain of the third transistor and the first terminal of the voltage-to-current converter circuit, a source of the third transistor is electrically connected to a drain of the fourth transistor, a gate of the fourth transistor is electrically connected to a second output terminal of the first differential transconductance amplifier, a gate of the second transistor is electrically connected to a first output terminal of the first differential transconductance amplifier, a non-inverting input terminal of the first differential transconductance amplifier is electrically connected to the output terminal of the control voltage output circuit, an inverting input terminal of the first differential transconductance amplifier is electrically connected to the output terminal of the first voltage output circuit, a gate of the first transistor and a gate of the third transistor are both configured to receive a second control signal, the second control signal being used to control turn-on or turn-off of the first transistor and the third transistor, and a source of the second transistor and a source of the fourth transistor are both grounded.

In some embodiments, the first voltage output circuit includes: a fifth transistor and a first resistor. A gate of the fifth transistor is electrically connected to the first input terminal of the error amplifier, a drain of the fifth transistor, and the output terminal of the current mirror, a source of the fifth transistor is electrically connected to a first terminal of the first resistor, and a second terminal of the first resistor is grounded.

In some embodiments, the voltage-to-current converter circuit includes: a sixth transistor and a second resistor. A gate of the sixth transistor is electrically connected to the input terminal of the first driver circuit and the output terminal of the error amplifier, a drain of the sixth transistor is electrically connected to the input terminal of the current mirror, a source of the sixth transistor is electrically connected to a first terminal of the second resistor, and a second terminal of the second resistor is electrically connected to the ground terminal of the first driver circuit.

In some embodiments, the control voltage output circuit includes: a second differential transconductance amplifier, a current source, an N-type transistor, and a second capacitor.

A non-inverting input terminal of the second differential transconductance amplifier is configured to receive the reference voltage, an inverting input terminal of the second differential transconductance amplifier is configured to receive the feedback voltage, an output terminal of the second differential transconductance amplifier is electrically connected to a gate of the N-type transistor, an input terminal of the current source is configured to be connected to a second power supply voltage, an output terminal of the current source is electrically connected to a drain of the N-type transistor, an upper plate of the second capacitor is electrically connected between the output terminal of the current source and the drain of the N-type transistor, the upper plate of the second capacitor is further electrically connected to the input terminal of the level shifter circuit, and a lower plate of the second capacitor and a source of the N-type transistor are both grounded.

The second differential transconductance amplifier is configured to, based on the reference voltage and the feedback voltage, control the N-type transistor to be turned on, to convert a voltage difference between the reference voltage and the feedback voltage into a current, such that the control voltage is generated.

In a second aspect, some embodiments of the present disclosure provide a switched-capacitor converter. The switched-capacitor converter includes: a first group of power transistors, a second group of power transistors, a first driver circuit, a second driver circuit, a plurality of flying capacitors, and the control circuit according to the first aspect or the embodiments of the first aspect.

The first driver circuit is configured to drive the first group of power transistors to switch between a turned-on state and a turned-off state.

The second driver circuit is configured to drive the second group of power transistors to switch between a turned-on state and a turned-off state.

The first group of power transistors and the second group of power transistors are configured to, during switching between the turned-on state and the turned-off state, control the plurality of flying capacitors to switch between charging and discharging, to convert an input voltage of the switched-capacitor converter into a plurality of output voltages.

The control circuit is configured to control a turn-on voltage of the first group of power transistors, to control an input current or an output current or an output voltage of the switched-capacitor converter.

For details about the beneficial effects achieved by the switched-capacitor converter according to the second aspect and the embodiments of the second aspect, reference may be made to the beneficial effects achieved by the first aspect or the embodiments of the first aspect, which are not described herein any further.

In a third aspect, some embodiments of the present disclosure provide a chip. The chip includes: the control circuit according to the first aspect and various embodiments thereof, and/or the switched-capacitor converter according to the first aspect.

In a fourth aspect, some embodiments of the present disclosure provide an electronic device. The electronic device includes: the chip according to the third aspect.

The above description only summarizes the technical solutions of the embodiments of the present disclosure. Specific embodiments of the present disclosure are described hereinafter to better and clearer understand the technical solutions of the embodiments of the present disclosure, to practice the technical solutions based on the disclosure of the specification and to make the above and other objectives, features and advantages of the embodiments of the present disclosure more apparent and understandable.

### BRIEF DESCRIPTION OF THE DRAWINGS

For clearer descriptions of technical solutions according to the embodiments of the present disclosure, drawings that are to be referred for description of the embodiments are briefly described hereinafter. Apparently, the drawings described hereinafter merely illustrate some embodiments of the present disclosure. Persons of ordinary skill in the art may also derive other drawings based on the drawings described herein without any creative effort.

FIG. 1 is a schematic structural diagram of a switched-capacitor converter according to some embodiments of the present disclosure.

FIG. 2 is a schematic structural diagram of another switched-capacitor converter according to some embodiments of the present disclosure.

FIG. 3 is a schematic structural diagram of yet another switched-capacitor converter according to some embodiments of the present disclosure.

FIG. 4 is a schematic diagram of a partial circuit of yet another control circuit according to some embodiments of the present disclosure.

FIG. 5 is a schematic diagram illustrating a relationship between a gate voltage of the first power transistor and an input voltage of the first driver circuit in FIGS. 1 to 4.

FIG. 6 is a schematic structural diagram of yet another switched-capacitor converter according to some embodiments of the present disclosure.

### DETAILED DESCRIPTION OF THE EMBODIMENTS

In the present disclosure, the term “at least one” refers to one or more than one, and the term “a plurality of” refers to two or more than two. The term “and/or” is merely an association relationship for describing associated objects, which represents that there may exist three types of relationships. For example, the phrase “A and/or B” means (A), (B), or (A and B), wherein A and B may be single or plural. In addition, the symbol “/” generally represents an “or” relationship between associated objects before and after the symbol. The expression “at least one of the following” or the like expression means any combination of the items or options listed, including a single item or option or any combination of plural items or options listed. For example, at least one of a single a, a single b, and a single c may indicate: the single a, the single b, the single c, a combination of a and b, a combination of a and c, a combination of b and c, or a combination of a, b, and c, wherein each of a, b, and c may be single or plural. In addition, the terms “first,” “second,” and the like are merely for the illustration purpose, and shall not be construed as indicating or implying a relative importance.

In the description of the present disclosure, it should be understood that the terms “central,” “transversal,” “longitudinal,” “upper,” “lower,” “left,” “right,” “front,” “rear,” and the like indicate orientations and position relationships which are based on the illustrations in the accompanying drawings, and these terms are merely for ease and brevity of the description, instead of indicating or implying that the devices or elements shall have a particular orientation and shall be structured and operated based on the particular orientation. Accordingly, these terms shall not be construed as limiting the present disclosure.

In the description of the present disclosure, unless otherwise explicitly specified and defined, the terms “connected,” “coupled,” and derivatives forms thereof shall be understood in a broad sense. For example, the terms “connected,” “coupled,” and derivatives form thereof for depicting the circuit structure, in addition to physical connection, may also be understood as electrical connections or signal connection. The connection, for example, may be direct connection, i.e., the physical connection or, indirect connection via at least one intermediate element as long as the circuit is turned on, or communication between the interiors of two elements. The signal connection, in addition to signal connection via a circuitry, may also be signal connection via a communication medium, for example, radio waves. Persons of ordinary skill in the art may understand specific meanings of the above terms in the present disclosure according to the actual circumstances and contexts.

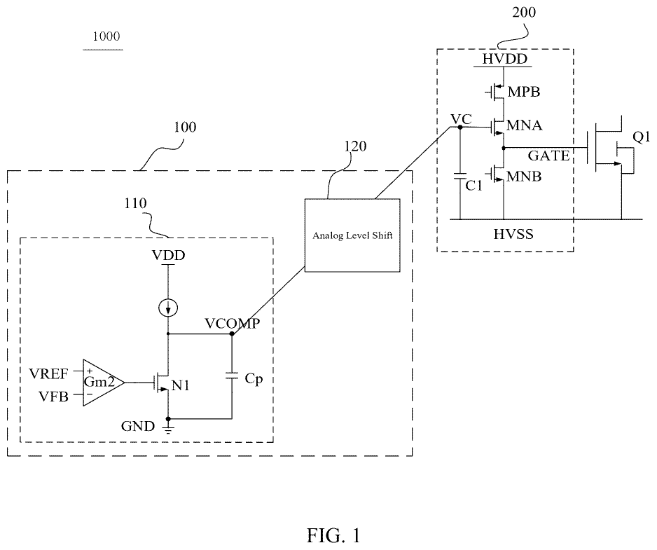

FIG. 1 is a schematic structural diagram of a switched-capacitor converter 1000 according to some embodiments of the present disclosure. As illustrated in FIG. 1, the switched-capacitor converter 1000 includes: a control circuit 100, a first driver circuit 200, and a first power transistor Q1, which are electrically connected. The control circuit 100 may include: a control voltage output circuit 110 and a level shifter circuit 120.

A first input terminal of the control voltage output circuit 110 is configured to receive a reference voltage VREF, and a second input terminal of the control voltage output circuit 110 is configured to receive a feedback voltage VFB. The feedback voltage VFB is used to represent a conversion of an input current or an output current or an output voltage of the switched-capacitor converter 1000. An output terminal of the control voltage output circuit 110 is electrically connected to an input terminal of the level shifter circuit 120. An output terminal of the level shifter circuit 120 is electrically connected to an input terminal of the first driver circuit 200. An output terminal of the first driver circuit 200 is electrically connected to a gate of the first power transistor Q1. A ground terminal of the first driver circuit 200 is electrically connected to a source of the first power transistor Q1.

It should be noted that the control voltage output circuit 110 and the level shifter circuit 120 may be implemented separately or may be integrated, which is not specifically limited in the embodiments of the present disclosure.

The feedback voltage VFB is acquired by detecting the input current or the output current or the output voltage of the switched-capacitor converter 1000 using a corresponding detection circuit.

The control circuit 100 is a regulation control circuit that implements a constant-current function for the input current or the output current of the switched-capacitor converter 1000, and a constant-voltage function for the output voltage of the switched-capacitor converter 1000.

The control voltage output circuit 110 is configured to acquire a control voltage VCOMP based on the reference voltage VREF and the feedback voltage VFB. Furthermore, the control voltage output circuit 110 may transmit the control voltage VCOMP to the level shifter circuit 120, such that the level shifter circuit 120 acquires the control voltage VCOMP.

The control voltage VCOMP is used to control an input voltage VC of the first driver circuit 200. That is, the control voltage VCOMP is used to control a voltage difference VC-HVSS between the input voltage VC of the first driver circuit 200 and a voltage HVSS at the ground terminal of the first driver circuit 200. The voltage at the input terminal of the first driver circuit 200 is the input voltage VC of the first driver circuit 200.

In this way, the level shifter circuit 120 may shift the control voltage VCOMP into a voltage domain where the first driver circuit 200 is located, such that the voltage difference VC-HVSS between the input voltage VC of the first driver circuit 200 and the voltage HVSS at the ground terminal of the first driver circuit 200 is equal to the control voltage VCOMP.

A maximum gate voltage that the first power transistor Q1, when turned on, may reach is the input voltage VC of the first driver circuit 200, and a source voltage of the first power transistor Q1 is equal to the voltage HVSS at the ground terminal of the first driver circuit 200. Therefore, the control circuit 100 may control the voltage difference VC-HVSS between the input voltage VC of the first driver circuit 200 and the voltage HVSS at the ground terminal of the first driver circuit 200 by using the control voltage VCOMP.

Hence, the control circuit 100 may control a turn-on voltage of the first power transistor Q1 by using the control voltage VCOMP, thereby controlling the input current or the output current or the output voltage. As a consequence, an impedance of the switched-capacitor converter 1000 is changed and closed-loop negative feedback is implemented. This prevents overvoltage and overcurrent issues or other hazardous operating conditions from occurring in a case where the switched-capacitor converter 1000 is in an abnormal operating state.

In a case where the feedback voltage VFB represents the conversion of the input current of the switched-capacitor converter 1000, the control circuit 100 may control the input current of the switched-capacitor converter 1000 by using the control voltage VCOMP. In a case where the feedback voltage VFB represents the conversion of the output current of the switched-capacitor converter 1000, the control circuit 100 may control the output current of the switched-capacitor converter 1000 by using the control voltage VCOMP. When the feedback voltage VFB represents the conversion of the output voltage of the switched-capacitor converter 1000, the control circuit 100 may control the output voltage of the switched-capacitor converter 1000 by using the control voltage VCOMP.

In the switched-capacitor converter according to the present disclosure, the control voltage output circuit may acquire the control voltage based on the reference voltage and the feedback voltage, and transmit the control voltage to the level shifter circuit, such that the level shifter circuit acquires the control voltage. In this way, the level shifter circuit may shift the control voltage into the voltage domain of the first driver circuit, such that the control voltage is enabled to control the voltage difference between the input voltage of the first driver circuit and the voltage at the ground terminal of the first driver circuit. Hence, the control circuit may control the turn-on voltage of the first power transistor by using the control voltage, to control the input current or the output current or the output voltage. Consequently, the impedance of the switched-capacitor converter is changed. This prevents overvoltage and overcurrent issues or other hazardous operating conditions from occurring in a case where the switched-capacitor converter is in an abnormal operating state.

Based on the description of the above embodiments, the level shifter circuit 120 may be implemented in various feasible ways.

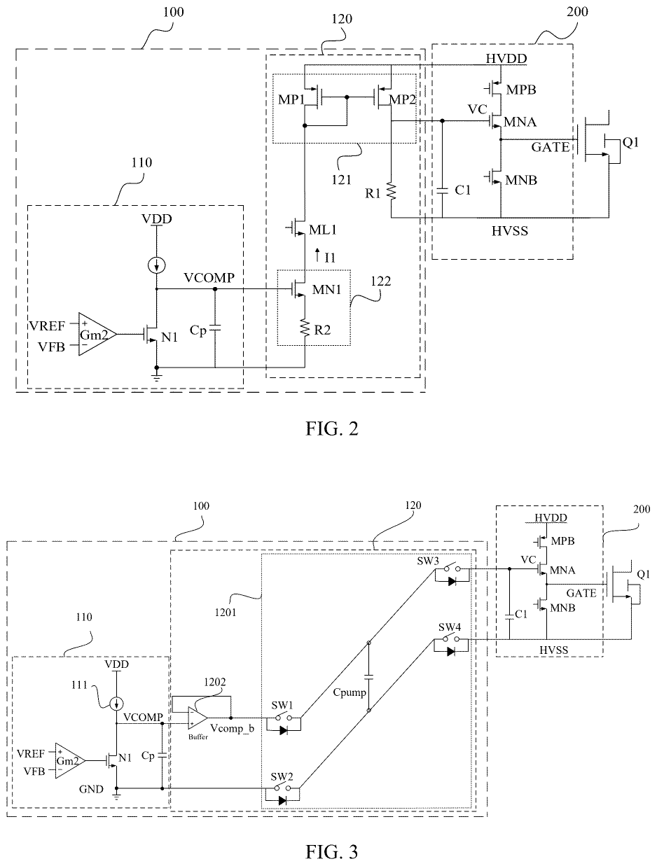

For a feasible implementation of the level shifter circuit 120, reference may be made to FIG. 2. FIG. 2 is a schematic structural diagram of another switched-capacitor converter according to some embodiments of the present disclosure. As illustrated in FIG. 2, the level shifter circuit 120 may include: a current mirror 121, a voltage-to-current conversion circuit 122, a first transistor ML1, and a first resistor R1.

An input terminal of the voltage-to-current conversion circuit 122 is electrically connected to the output terminal of the control voltage output circuit 110. An output terminal of the voltage-to-current conversion circuit 122 is electrically connected to a source of the first transistor ML1. A gate of the first transistor ML1 is configured to receive a control signal, and the control signal is used to control the first transistor ML1 to be turned on or turned off. A drain of the first transistor ML1 is electrically connected to an input terminal of the current mirror 121. An output terminal of the current mirror 121 is electrically connected to a first terminal of the first resistor R1 and the input terminal of the first driver circuit 200. A second terminal of the first resistor R1 is electrically connected to the ground terminal of the first driver circuit 200.

It should be noted that the input terminal of the voltage-to-current conversion circuit 122 is the input terminal of the level shifter circuit 120, and the first terminal of the first resistor R1 is the output terminal of the level shifter circuit 120.

The first transistor ML1 is a high-voltage transistor, configured to withstand a high voltage, i.e., a first power supply voltage HVDD.

The voltage-to-current conversion circuit 122 may convert the control voltage VCOMP into a first current I1. Furthermore, the voltage-to-current conversion circuit 122 may transmit the first current I1 to the current mirror 121 via the first transistor ML1, such that the current mirror 121 acquires the first current I1.

In this way, the current mirror 121 may transmit the first current I1 to the first resistor R1, such that the first current I1 passes through the first resistor R1. Hence, the voltage at the first terminal of the first resistor R1 is the input voltage VC of the first driver circuit 200, and a voltage across the first resistor R1 is equal to the control voltage VCOMP, such that the control voltage VCOMP falls within the voltage domain. Thus, the level shifter circuit 120 may shift the control voltage VCOMP into the voltage domain of the first driver circuit 200, thereby achieving the shifting of an analog voltage.

In summary, the voltage-to-current conversion circuit may convert the control voltage into the first current and transmit the first current to the current mirror via the first transistor, such that the current mirror acquires the first current. In this way, the current mirror may transmit the first current to the first resistor, such that the voltage across the first resistor is the control voltage, and the control voltage falls within the voltage domain. Thus, the level shifter circuit may shift the control voltage into the voltage domain.

Based on the description of the above embodiments, a possible implementation of the voltage-to-current conversion circuit 122 is provided as an example. As illustrated in FIG. 2, the voltage-to-current conversion circuit 122 may include: a second transistor MN1 and a second resistor R2.

A gate of the second transistor MN1 is electrically connected to the output terminal of the control voltage output circuit 110. A drain of the second transistor MN1 is electrically connected to the source of the first transistor ML1. A source of the second transistor MN1 is electrically connected to a first terminal of the second resistor R2. A second terminal of the second resistor R2 is grounded.

The gate of the second transistor MN1 is the input terminal of the voltage-to-current conversion circuit 122, and the drain of the second transistor MN1 is the output terminal of the voltage-to-current conversion circuit 122.

As an example, the second transistor MN1 is a depletion-type Native transistor.

The first current I1 may be expressed by Formula (1):

I1=VCOMP/r2 (1)

I1 denotes the first current, VCOMP denotes the control voltage, and r2 denotes a resistance of the second resistor R2.

A resistance of the first resistor R1 is equal to the resistance of the second resistor R2, therefore, the voltage across the first resistor R1 is the control voltage VCOMP.

Based on the description of the above embodiments, a possible implementation of the current mirror 121 is provided as an example. As illustrated in FIG. 2, the current mirror 121 may include: a first P-type transistor MP1 and a second P-type transistor MP2.

A source of the first P-type transistor MP1 and a source of the second P-type transistor MP2 are both configured to receive the first power supply voltage HVDD. A gate of the first P-type transistor MP1, a drain of the first P-type transistor MP1, and a gate of the second P-type transistor MP2 are all electrically connected to the drain of the first transistor ML1. A drain of the second P-type transistor MP2 is electrically connected to the first terminal of the first resistor R1.

The drain of the first P-type transistor MP1 is the input terminal of the current mirror 121, and the drain of the second P-type transistor MP2 is the output terminal of the current mirror 121.

For another feasible implementation of the level shifter circuit 120, reference may be made to FIG. 3. FIG. 3 is a schematic structural diagram of yet another switched-capacitor converter according to some embodiments of the present disclosure. As illustrated in FIG. 3, the level shifter circuit 120 may include: a charge pump 1201.

An input terminal of the charge pump 1201 is electrically connected to the output terminal of the control voltage output circuit 110, and an output terminal of the charge pump 1201 is electrically connected to the input terminal of the first driver circuit 200.

The input terminal of the charge pump 1201 is the input terminal of the level shifter circuit 120, and the output terminal of the charge pump 1201 is the output terminal of the level shifter circuit 120.

In a first stage, the charge pump 1201 may store charge using a first capacitor Cpump of the charge pump 1201, such that a voltage across the first capacitor Cpump is the control voltage. Then, in a second stage, the charge pump 1201 may release the charge stored in the first capacitor Cpump, such that the charge stored in the capacitor Cpump is transferred to a circuit between the input terminal of the first driver circuit 200 and the ground terminal of the first driver circuit 200. Hence, the charge pump 1201 may shift the control voltage VCOMP into the voltage domain. In this way, the level shifter circuit 120 may shift the control voltage VCOMP into the voltage domain.

In summary, in the first stage, the charge pump may store the charge corresponding to the control voltage by using the first capacitor in the charge pump, and in the second stage, release the charge stored in the first capacitor, such that the control voltage is shifted into the voltage domain. Thus, the level shifter circuit may shift the control voltage into the voltage domain.

Based on the description of the above embodiments, a possible implementation of the charge pump 1201 is provided as an example. As illustrated in FIG. 3, the charge pump 1201 may include: a first switching transistor SW1, a second switching transistor SW2, a third switching transistor SW3, a fourth switching transistor SW4, and the first capacitor Cpump.

A first terminal of the first switching transistor SW1 is electrically connected to the output terminal of the control voltage output circuit 110. A second terminal of the first switching transistor SW1 is electrically connected to a first terminal of the third switching transistor SW3. A second terminal of the third switching transistor SW3 is electrically connected to the input terminal of the first driver circuit 200. A first terminal of the second switching transistor SW2 is grounded. A second terminal of the second switching transistor SW2 is electrically connected to a first terminal of the fourth switching transistor SW4. A second terminal of the fourth switching transistor SW4 is electrically connected to the ground terminal of the first driver circuit 200. An upper plate of the first capacitor Cpump is electrically connected between the second terminal of the first switching transistor SW1 and the first terminal of the third switching transistor SW3. A lower plate of the first capacitor Cpump is electrically connected between the second terminal of the second switching transistor SW2 and the first terminal of the fourth switching transistor SW4. Control terminals of the first switching transistor SW1, the second switching transistor SW2, the third switching transistor SW3, and the fourth switching transistor SW4 are all configured to receive a control signal, wherein the control signal is used to control the first switching transistor SW1, the second switching transistor SW2, the third switching transistor SW3, and the fourth switching transistor SW4 to be turned on or turned off.

The first terminal of the first switching transistor SW1 is the input terminal of the charge pump 1201, and the second terminal of the third switching transistor SW3 is the output terminal of the charge pump 1201.

The first switching transistor SW1, the second switching transistor SW2, the third switching transistor SW3, and the fourth switching transistor SW4 may include, but are not limited to, gallium nitride (GaN) transistors, insulated gate bipolar transistors (IGBTs), and metal-oxide-semiconductor field-effect transistors (MOSFETs).

For example, in a case where the first switching transistor SW1, the second switching transistor SW2, the third switching transistor SW3, and the fourth switching transistor SW4 are GaN transistors, the control terminal of each of these switching transistors refers to a gate of the GaN transistor. The first terminal of each of these switching transistors may be a drain or a source of the GaN transistor, and correspondingly, the second terminal of each of the switching transistors may be the source or the drain of the GaN transistor.

For example, in a case where the first switching transistor SW1, the second switching transistor SW2, the third switching transistor SW3, and the fourth switching transistor SW4 are MOSFETs, the control terminal of each of these switching transistors refers to a gate of the MOSFET. The first terminal of each of these switching transistors may be a drain or a source of the MOSFET, and correspondingly, the second terminal of each of the switching transistors may be the source or the drain of the MOSFET.

For example, in a case where the first switching transistor SW1, the second switching transistor SW2, the third switching transistor SW3, and the fourth switching transistor SW4 are field-controlled thyristors, the control terminal of each of these switching transistors refers to a gate of the field-controlled thyristor. The first terminal of each of these switching transistors may be a drain or a source of the field-controlled thyristor, and correspondingly, the second terminal of each of the switching transistors may be the source or the drain of the field-controlled thyristor.

In the first stage, the first switching transistor SW1 and the second switching transistor SW2 are turned on, and the third switching transistor SW3 and the fourth switching transistor SW4 are turned off, in this case, the first capacitor Cpump may store charge, such that the voltage across the first capacitor Cpump is equal to the control voltage VCOMP. In the second stage, the first switching transistor SW1 and the second switching transistor SW2 are turned off, and the third switching transistor SW3 and the fourth switching transistor SW4 are turned on, in this case, the first capacitor Cpump may release charge, such that the charge stored in the first capacitor Cpump is transferred to a circuit between the input terminal of the first driver circuit 200 and the ground terminal of the first driver circuit 200.

Based on the description of the above embodiments, a possible implementation of the level shifter circuit 120 is provided as an example. As illustrated in FIG. 3, the level shifter circuit 120 may further include: a buffer 1202.

The buffer 1202 has a unity gain of 1.

A non-inverting input terminal of the buffer 1202 is electrically connected to the output terminal of the control voltage output circuit 110. An inverting input terminal of the buffer 1202 is electrically connected to both an output terminal of the buffer 1202 and the input terminal of the charge pump 1201.

The non-inverting input terminal of the buffer 1202 is the input terminal of the level shifter circuit 120, and the output terminal of the charge pump 1201 is the output terminal of the level shifter circuit 120.

The buffer 1202 may amplify the control voltage VCOMP with a gain of one, and hence an amplified control voltage Vcomp_b is acquired. Since the buffer 1202 has a unity gain of 1, an amplitude of the amplified control voltage Vcomp_b is equal to an amplitude of the control voltage VCOMP. This eliminates interference signals generated during the turn-on and turn-off of the first switching transistor SW1 in the charge pump 1201, thereby eliminating interference such as the clock feedthrough effect and improving the control accuracy of the control circuit 100.

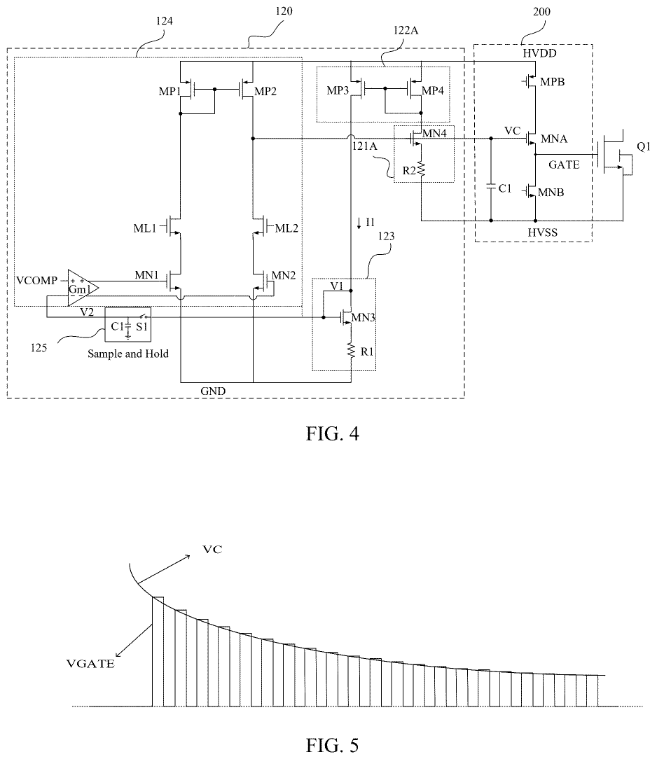

For yet another feasible implementation of the level shifter circuit 120, reference may be made to FIG. 4. FIG. 4 is a schematic diagram of a partial circuit of yet another switched-capacitor converter according to some embodiments of the present disclosure. As illustrated in FIG. 4, the level shifter circuit 120 may include: a voltage-to-current conversion circuit 121A, a current mirror 122A, a first voltage output circuit 123, and an error amplifier 124.

This implementation of the level shifter circuit 120 is based on negative feedback.

A first terminal of the voltage-to-current conversion circuit 121A is electrically connected to an input terminal of the current mirror 122A, the input terminal of the first driver circuit 200, and an output terminal of the error amplifier 124. A second terminal of the voltage-to-current conversion circuit 121A is electrically connected to the ground terminal of the first driver circuit 200. An output terminal of the current mirror 122A is electrically connected to an input terminal of the first voltage output circuit 123. An output terminal of the first voltage output circuit 123 is electrically connected to a first input terminal of the error amplifier 124. A second input terminal of the error amplifier 124 is electrically connected to the output terminal of the control voltage output circuit 110.

The second input terminal of the error amplifier 124 is the input terminal of the level shifter circuit 120, and the first terminal of the voltage-to-current conversion circuit 121A is the output terminal of the level shifter circuit 120.

The voltage-to-current conversion circuit 121A may convert the input voltage VC of the first driver circuit 200 into a first current I1. Furthermore, the voltage-to-current conversion circuit 121A may transmit the first current I1 to the current mirror 122A, such that the current mirror 122A acquires the first current I1.

In this way, the current mirror 122A may transmit the first current I1 to the first voltage output circuit 123. Thus, the first voltage output circuit 123 may generate a first voltage V1 based on the first current I1. Furthermore, the first voltage output circuit 123 may transmit the first voltage V1 to the error amplifier 124, such that the error amplifier 124 acquires the first voltage V1.

The first voltage V1 is used to represent a variation of the input voltage VC of the first driver circuit 200.

Hence, the error amplifier 124 may, based on the control voltage VCOMP and the first voltage V1, maintain the stability of the voltage difference VC-HVSS, such that the voltage difference VC-HVSS is equal to the control voltage VCOMP. Thus, the level shifter circuit 120 may shift the control voltage VCOMP into the voltage domain, thereby achieving an analog voltage shift.

In summary, the voltage-to-current conversion circuit may convert the input voltage of the first driver circuit into the first current and transmit the first current to the current mirror, such that the current mirror acquires the first current. In this way, the current mirror may transmit the first current to the first voltage output circuit. Thus, the first voltage output circuit may, based on the first current, generate the first voltage for representing the variation of the input voltage of the first driver circuit, and transmit the first voltage to the error amplifier, such that the error amplifier acquires the first voltage. Hence, the error amplifier may, based on the control voltage and the first voltage, maintain the stability of the voltage difference, to shift the control voltage into the voltage domain.

Based on the description of the above embodiments, a possible implementation of the error amplifier 124 is provided as an example. As illustrated in FIG. 4, the error amplifier 124 may include: a first differential transconductance amplifier Gm1, a first P-type transistor MP1, a second P-type transistor MP2, a first transistor ML1, a second transistor MN1, a third transistor ML2, and a fourth transistor MN2.

A source of the first P-type transistor MP1 and a source of the second P-type transistor MP2 are both configured to receive a first power supply voltage. A gate of the first P-type transistor MP1, a drain of the first P-type transistor MP1, and a gate of the second P-type transistor MP2 are all electrically connected to a drain of the first transistor ML1. A source of the first transistor ML1 is electrically connected to a drain of the second transistor MN1. A drain of the second P-type transistor MP2 is electrically connected to both a drain of the third transistor ML2 and the first terminal of the voltage-to-current conversion circuit 121A. A source of the third transistor ML2 is electrically connected to a drain of the fourth transistor MN2. A gate of the fourth transistor MN2 is electrically connected to a second output terminal of the first differential transconductance amplifier Gm1. A gate of the second transistor MN1 is electrically connected to a first output terminal of the first differential transconductance amplifier Gm1. A non-inverting input terminal of the first differential transconductance amplifier Gm1 is electrically connected to the output terminal of the control voltage output circuit 110. An inverting input terminal of the first differential transconductance amplifier Gm1 is electrically connected to the output terminal of the first voltage output circuit 123. A gate of the first transistor ML1 and a gate of the third transistor ML2 are both configured to receive a second control signal, and the second control signal is used to control the first transistor ML1 and the third transistor ML2 to be turned on or turned off. A source of the second transistor MN1 and a source of the fourth transistor MN2 are both grounded.

The non-inverting input terminal of the first differential transconductance amplifier Gm1 is the second input terminal of the error amplifier 124. The inverting input terminal of the first differential transconductance amplifier Gm1 is the first input terminal of the error amplifier 124. The drain of the second P-type transistor MP2 is the output terminal of the error amplifier 124.

The first transistor ML1 and the third transistor ML2 are high-voltage transistors. The first transistor ML1 and the third transistor ML2 are configured to withstand a high voltage, i.e., the first power supply voltage HVDD.

Based on the description of the above embodiments, a possible implementation of the first voltage output circuit 123 is provided as an example. As illustrated in FIG. 4, the first voltage output circuit 123 may include: a fifth transistor MN3 and a first resistor R1.

A gate of the fifth transistor MN3 is electrically connected to the first input terminal of the error amplifier 124, a drain of the fifth transistor MN3, and the output terminal of the current mirror 122A. A source of the fifth transistor MN3 is electrically connected to a first terminal of the first resistor R1. A second terminal of the first resistor R1 is grounded.

The drain of the fifth transistor MN3 is the input terminal of the first voltage output circuit 123, and the gate of the fifth transistor MN3 is the output terminal of the first voltage output circuit 123.

After passing through the fifth transistor MN3 and the first resistor R1, the first current I1 is used to generate the first voltage V1. The first voltage V1 may be expressed by Formula (2):

V1=I1*r1+Vth1 (2)

V1 denotes the first voltage, I1 denotes the first current, r1 denotes a resistance of the first resistor R1, and Vth1 denotes a threshold voltage of the fifth transistor MN3.

Based on the description of the above embodiments, a possible implementation of the voltage-to-current conversion circuit 121A is provided as an example. As illustrated in FIG. 4, the voltage-to-current conversion circuit 121A may include: a sixth transistor MN4 and a second resistor R2.

A gate of the sixth transistor MN4 is electrically connected to both the input terminal of the first driver circuit 200 and the output terminal of the error amplifier 124. A drain of the sixth transistor MN4 is electrically connected to the input terminal of the current mirror 122A. A source of the sixth transistor MN4 is electrically connected to a first terminal of the second resistor R2. A second terminal of the second resistor R2 is electrically connected to the ground terminal of the first driver circuit 200.

The gate of the sixth transistor MN4 is the first terminal of the voltage-to-current conversion circuit 121A, and the second terminal of the second resistor R2 is the second terminal of the voltage-to-current conversion circuit 121A.

The input voltage VC of the first driver circuit 200 may be converted into the first current I1 by the sixth transistor MN4 and the second resistor R2. The first current I1 may be expressed by Formula (3):

I1=(VC−Vth2)/r2 (3)

I1 denotes the first current, VC denotes the input voltage of the first driver circuit 200, Vth2 denotes a threshold voltage of the sixth transistor MN4, and r2 denotes a resistance of the second resistor R2.

The resistance of the first resistor R1 is equal to the resistance of the second resistor R2. Therefore, the first voltage V1 is equal to the input voltage VC of the first driver circuit 200.

Based on the description of the above embodiments, another possible implementation of the level shifter circuit 120 is provided as an example. As illustrated in FIG. 4, the level shifter circuit 120 may further include: a sample-and-hold circuit 125.

An input terminal of the sample-and-hold circuit 125 is electrically connected to the output terminal of the first voltage output circuit 123. An output terminal of the sample-and-hold circuit 125 is electrically connected to the first input terminal of the error amplifier 124.

The sample-and-hold circuit 125 may, in a case where the first power transistor Q1 is turned on, sample and hold the first voltage V1 to acquire a second voltage V2. Furthermore, the sample-and-hold circuit 125 may transmit the second voltage V2 to the error amplifier 124, such that the error amplifier 124 acquires the second voltage V2. In this way, the error amplifier 124 may, based on the control voltage VCOMP and the second voltage V2, maintain the stability of the voltage difference VC-HVSS, thereby improving the stability of the error amplifier 124. This, in turn, improves the control accuracy of the control circuit 100 over the turn-on voltage of the first power transistor Q1.

Based on the description of the above embodiments, a possible implementation of the sample-and-hold circuit 125 is provided as an example. As illustrated in FIG. 4, the sample-and-hold circuit 125 may include: a fifth switching transistor S1 and a third capacitor C1.

A first terminal of the fifth switching transistor S1 is electrically connected to the output terminal of the first voltage output circuit 123. A control terminal of the fifth switching transistor S1 is configured to receive a first control signal, wherein the first control signal is used to control the fifth switching transistor S1 to be turned on or turned off. A second terminal of the fifth switching transistor S1 is electrically connected to the first input terminal of the error amplifier 124. An upper plate of the third capacitor C1 is electrically connected between the second terminal of the fifth switching transistor S1 and the first input terminal of the error amplifier 124. A lower plate of the third capacitor C1 is grounded.

The first terminal of the fifth switching transistor S1 is the input terminal of the sample-and-hold circuit 125, and the upper plate of the third capacitor C1 is the output terminal of the sample-and-hold circuit 125.

Based on the description of the above embodiments, a possible implementation of the control voltage output circuit 110 is provided as an example. As illustrated in FIGS. 1 to 3, the control voltage output circuit 110 may include: a second differential transconductance amplifier Gm2, a current source 111, an N-type transistor N1, and a second capacitor Cp.

A non-inverting input terminal of the second differential transconductance amplifier Gm2 is configured to receive the reference voltage VREF. An inverting input terminal of the second differential transconductance amplifier Gm2 is configured to receive the feedback voltage VFB. An output terminal of the second differential transconductance amplifier Gm2 is electrically connected to a gate of the N-type transistor N1. An input terminal of the current source 111 is configured to receive a second power supply voltage VDD. An output terminal of the current source 111 is electrically connected to a drain of the N-type transistor N1. An upper plate of the second capacitor Cp is electrically connected between the output terminal of the current source 111 and the drain of the N-type transistor N1. The upper plate of the second capacitor Cp is further electrically connected to the input terminal of the level shifter circuit 120. A lower plate of the second capacitor Cp and a source of the N-type transistor N1 are both grounded.

The non-inverting input terminal of the second differential transconductance amplifier Gm2 is the first input terminal of the control voltage output circuit 110. The inverting input terminal of the second differential transconductance amplifier Gm2 is the second input terminal of the control voltage output circuit 110. The upper plate of the second capacitor Cp is the output terminal of the control voltage output circuit 110.

The second differential transconductance amplifier Gm2 may amplify a voltage difference between the reference voltage VREF and the feedback voltage VFB, and control the N-type transistor N1 to be turned on. In this way, the voltage difference between the reference voltage VREF and the feedback voltage VFB is converted into a current and compared with a reference current output by the current source 111 to generate the control voltage VCOMP.

Based on the description of the above embodiments, a possible implementation of the first driver circuit 200 is provided as an example. As illustrated in FIGS. 1 to 4, the first driver circuit 200 may include: a seventh transistor MPB, an eighth transistor MNA, a ninth transistor MNB, and a capacitor C1.

A source of the seventh transistor MPB is configured to receive the first power supply voltage HVDD. A drain of the seventh transistor MPB is electrically connected to a drain of the eighth transistor MNA. A gate of the eighth transistor MNA is electrically connected to the output terminal of the level shifter circuit 120. A source of the eighth transistor MNA is electrically connected to a drain of the ninth transistor MNB. An upper plate of the capacitor C1 is electrically connected between the gate of the eighth transistor MNA and the output terminal of the level shifter circuit 120. A lower plate of the capacitor C1 and a source of the ninth transistor MNB are both electrically connected to the source of the first power transistor Q1.

Hereinafter, with reference to FIG. 5, which is a schematic diagram illustrating a relationship between a gate voltage of the first power transistor and an input voltage of the first driver circuit illustrated in FIGS. 1 to 4, the relationship between a gate voltage VGATE of the first power transistor Q1 and the input voltage VC of the first driver circuit 200 is described in detail.

As illustrated in FIG. 5, in a case where the first power transistor Q1 is turned on, the seventh transistor MPB is turned on and the ninth transistor MNB is turned off, such that the gate voltage VGATE of the first power transistor Q1 rises. In this case, a maximum voltage that the gate voltage VGATE of the first power transistor Q1 may reach is the input voltage VC of the first driver circuit 200.

In a case where the first power transistor Q1 is turned off, the seventh transistor MPB is turned off and the ninth transistor MNB is turned on, such that the gate voltage VGATE of the first power transistor Q1 falls. In this case, the gate voltage VGATE of the first power transistor Q1 is pulled down to the voltage HVSS at the ground terminal of the first driver circuit 200.

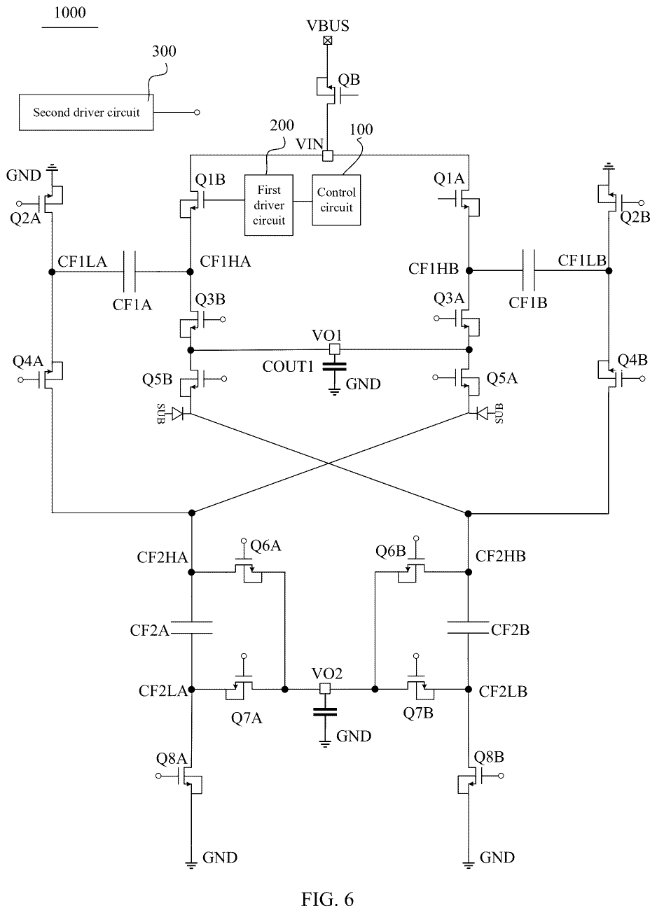

FIG. 6 is a schematic structural diagram of yet another switched-capacitor converter according to some embodiments of the present disclosure. As illustrated in FIG. 6, a switched-capacitor converter 1000 may include: a first group of power transistors, a second group of power transistors, a first driver circuit 200, a second driver circuit 300, a plurality of flying capacitors CF, and a control circuit 100.

The first driver circuit 200 may drive the power transistors of the first group of power transistors to switch between a turned-on state and a turned-off state.

The second driver circuit 300 may drive the power transistors of the second group of power transistors to switch between a turned-on state and a turned-off state.

During switching between the turned-on state and the turned-off state, the first group of power transistors and the second group of power transistors may control the plurality of flying capacitors CF to switch between charging and discharging, to convert an input voltage of the switched-capacitor converter 1000 into a plurality of output voltages.

The control circuit 100 may control a turn-on voltage of the first group of power transistors to control an input current or an output current or an output voltage of the switched-capacitor converter 1000.

The plurality of flying capacitors CF may include: a first flying capacitor CF1A, a second flying capacitor CF1B, a third flying capacitor CF2A, and a fourth flying capacitor CF2B.

The first group of power transistors include two power transistors: a third power transistor Q1A and a fourth power transistor Q1B. Correspondingly, two first driver circuits 200 and two control circuits 100 are provided. For ease of description, FIG. 6 only schematically illustrates the first driver circuit 200 and the control circuit 100 corresponding to the fourth power transistor Q1B.

The second group of power transistors may include: a fifth power transistor Q2A, a sixth power transistor Q2B, a seventh power transistor Q3A, an eighth power transistor Q3B, a ninth power transistor Q4A, a tenth power transistor Q4B, an eleventh power transistor Q5A, a twelfth power transistor Q5B, a thirteenth power transistor Q6A, a fourteenth power transistor Q6B, a fifteenth power transistor Q7A, a sixteenth power transistor Q7B, a seventeenth power transistor Q8A, and an eighteenth power transistor Q8B.

A drain of the third power transistor Q1A and a drain of the fourth power transistor Q1B are both configured to receive an input voltage VIN of the switched-capacitor converter 1000. A source of the fourth power transistor Q1B is electrically connected to a drain of the eighth power transistor Q3B. A source of the eighth power transistor Q3B is electrically connected to a drain of the twelfth power transistor Q5B. A source of the third power transistor Q1A is electrically connected to a drain of the seventh power transistor Q3A. A source of the seventh power transistor Q3A is electrically connected to a drain of the eleventh power transistor Q5A. A source of the fifth power transistor Q2A and a source of the sixth power transistor Q2B are both grounded. A drain of the fifth power transistor Q2A is electrically connected to a source of the ninth power transistor Q4A. A drain of the sixth power transistor Q2B is electrically connected to a source of the tenth power transistor Q4B. A first output terminal O1 of the switched-capacitor converter 1000 is electrically connected between the source of the eighth power transistor Q3B and the drain of the twelfth power transistor Q5B. The first output terminal O1 of the switched-capacitor converter 1000 is further electrically connected between the source of the seventh power transistor Q3A and the drain of the eleventh power transistor Q5A.

A first plate of the first flying capacitor CF1A is electrically connected between the source of the fourth power transistor Q1B and the drain of the eighth power transistor Q3B. A second plate of the first flying capacitor CF1A is electrically connected between the drain of the fifth power transistor Q2A and the source of the ninth power transistor Q4A. A first plate of the second flying capacitor CF1B is electrically connected between the source of the fourth power transistor Q1B and the drain of the seventh power transistor Q3A. A second plate of the second flying capacitor CF1B is electrically connected between the drain of the sixth power transistor Q2B and the source of the tenth power transistor Q4B.

A drain of the ninth power transistor Q4A is electrically connected to a first plate of the third flying capacitor CF2A. A second plate of the third flying capacitor CF2A is electrically connected to a drain of the seventeenth power transistor Q8A. A source of the seventeenth power transistor Q8A is grounded. A source of the eleventh power transistor Q5A and a drain of the thirteenth power transistor Q6A are both electrically connected between the drain of the ninth power transistor Q4A and the first plate of the third flying capacitor CF2A. A source of the fifteenth power transistor Q7A is electrically connected between the second plate of the third flying capacitor CF2A and the drain of the seventeenth power transistor Q8A. A source of the thirteenth power transistor Q6A and a drain of the fifteenth power transistor Q7A are both electrically connected to a second output terminal O2 of the switched-capacitor converter 1000.

A drain of the tenth power transistor Q4B is electrically connected to a first plate of the fourth flying capacitor CF2B. A second plate of the fourth flying capacitor CF2B is electrically connected to a drain of the eighteenth power transistor Q8B. A source of the eighteenth power transistor Q8B is grounded. A source of the twelfth power transistor Q5B and a drain of the fourteenth power transistor Q6B are both electrically connected between the drain of the tenth power transistor Q4B and the first plate of the fourth flying capacitor CF2B. A source of the sixteenth power transistor Q7B is electrically connected between the second plate of the fourth flying capacitor CF2B and the drain of the eighteenth power transistor Q8B. A source of the fourteenth power transistor Q6B and a drain of the sixteenth power transistor Q7B are both electrically connected to the second output terminal O2 of the switched-capacitor converter 1000.

A gate of the third power transistor Q1A and a gate of the fourth power transistor Q1B are both electrically connected to the output terminal of the first driver circuit 200. A gate of each power transistor of the second group of power transistors is electrically connected to the second driver circuit 300.

In FIG. 6, CF1HA denotes a voltage of the first plate of the first flying capacitor CF1A, and CF1LA denotes a voltage of the second plate of the first flying capacitor CF1A. CF1HB denotes a voltage of the first plate of the second flying capacitor CF1B, and CF1LB denotes a voltage of the second plate of the second flying capacitor CF1B. CF2HA denotes a voltage of the first plate of the third flying capacitor CF2A, and CF2LA denotes a voltage of the second plate of the third flying capacitor CF2A. CF2HB denotes a voltage of the first plate of the fourth flying capacitor CF2B, and CF2LB denotes a voltage of the second plate of the fourth flying capacitor CF2B.

In the embodiments, the third power transistor Q1A and the fourth power transistor Q1B in the first group of power transistors may not be turned on simultaneously. In a case where the third power transistor Q1A is turned on and the fourth power transistor Q1B is turned off, the third power transistor Q1A serves as the first power transistor Q1, and the voltage HVSS at the ground terminal of the first driver circuit 200 is the voltage CF1HB of the first plate of the second flying capacitor CF1B. In a case where the fourth power transistor Q1B is turned on and the third power transistor Q1A is turned off, the fourth power transistor Q1B serves as the first power transistor Q1, and the voltage HVSS at the ground terminal of the first driver circuit 200 is the voltage CF1HA of the first plate of the first flying capacitor CF1A.

In a first phase Φ1, the fourth power transistor Q1B, the sixth power transistor Q2B, the fourteenth power transistor Q6B, the eighteenth power transistor Q8B, the seventh power transistor Q3A, the ninth power transistor Q4A, the eleventh power transistor Q5A, and the fifteenth power transistor Q7A are turned on; the third power transistor Q1A, the fifth power transistor Q2A, the seventeenth power transistor Q8A, the eighth power transistor Q3B, the tenth power transistor Q4B, the twelfth power transistor Q5B, and the sixteenth power transistor Q7B are turned off.

In a second phase Φ2, the fourth power transistor Q1B, the sixth power transistor Q2B, the fourteenth power transistor Q6B, the eighteenth power transistor Q8B, the seventh power transistor Q3A, the ninth power transistor Q4A, the eleventh power transistor Q5A, and the fifteenth power transistor Q7A are turned off; the third power transistor Q1A, the fifth power transistor Q2A, the seventeenth power transistor Q8A, the eighth power transistor Q3B, the tenth power transistor Q4B, the twelfth power transistor Q5B, and the sixteenth power transistor Q7B are turned on.

In a case where no load is applied at either the first output terminal O1 or the second output terminal O2, a bus voltage, an input voltage, a first output voltage, and a second output voltage of the switched-capacitor converter 1000 may be expressed by Formula (4):

VBUS=VIN=2*VO1=4*VO2 (4)

VBUS denotes the bus voltage of the switched-capacitor converter 1000, VIN denotes the input voltage, VO1 denotes the first output voltage, and VO2 denotes the second output voltage.

The first output voltage is a voltage at the first output terminal O1, the second output voltage is a voltage at the second output terminal O2, and the input voltage is a voltage at an input terminal of the switched-capacitor converter 1000.

In some examples, the switched-capacitor converter 1000 may further include: a sixth switching transistor QB.

A source of the sixth switching transistor QB is configured to receive the bus voltage VBUS, and a drain of the sixth switching transistor QB is electrically connected to the input voltage VIN.

A parasitic diode of the sixth switching transistor QB is oriented from the bus voltage VBUS to the input voltage VIN.

During normal operation of the switched-capacitor converter 1000, the sixth switching transistor QB is turned on. When the switched-capacitor converter 1000 is in an abnormal operating state, the sixth switching transistor QB is turned off to prevent a reverse current path from existing between the input voltage VIN and the bus voltage VBUS.

Some embodiments of the present disclosure further provide a chip. The chip includes: the control circuit 100 according to the embodiments illustrated in FIGS. 1 to 4, and/or the switched-capacitor converter 1000 according to the embodiments illustrated in FIG. 6.

The control circuit and the switched-capacitor converter may be integrated in a single chip, or may be integrated in different chips, which is not limited in the embodiments of the present disclosure.

The chip herein achieves the same technical effects as the control circuit according to the embodiments of the present disclosure, which are not described herein any further.

Some embodiments of the present disclosure further provide an electronic device. The electronic device includes: the chip as described above.

In the present disclosure, the electronic device may include, but is not limited to, a tablet computer, a sensor, a medical device, and a wireless communication device.

The electronic device herein achieves the same technical effects as the control circuit according to the embodiments of the present disclosure, which are not described herein any further.

It should be finally noted that the above embodiments are used only for illustrating the present disclosure, but are not intended to limit the protection scope of the present disclosure. Various modifications and replacements readily derived by those skilled in the art within technical content of the present disclosure shall fall within the protection scope of the present disclosure. Therefore, the protection scope of the present disclosure is subject to the appended claims.

What is claimed is:

1. A control circuit, applied in a switched-capacitor converter, the switched-capacitor converter comprising: a first power transistor and a first driver circuit, and the control circuit comprising: a control voltage output circuit and a level shifter circuit; wherein
a first input terminal of the control voltage output circuit is configured to receive a reference voltage, a second input terminal of the control voltage output circuit is configured to receive a feedback voltage, the feedback voltage being used to represent a conversion of an input current or an output current or an output voltage of the switched-capacitor converter, an output terminal of the control voltage output circuit is electrically connected to an input terminal of the level shifter circuit, an output terminal of the level shifter circuit is electrically connected to an input terminal of the first driver circuit, an output terminal of the first driver circuit is electrically connected to a gate of the first power transistor, and a ground terminal of the first driver circuit is electrically connected to a source of the first power transistor;
the control voltage output circuit is configured to, based on the reference voltage and the feedback voltage, acquire a control voltage and transmit the control voltage to the level shifter circuit, wherein the control voltage is used to control an input voltage of the first driver circuit; and
the level shifter circuit is configured to shift the control voltage into a voltage domain of the first driver circuit, such that the control circuit controls a turn-on voltage of the first power transistor using the control voltage, to control the input current or the output current or the output voltage.

2. The control circuit according to claim 1, wherein the level shifter circuit comprises: a current mirror, a voltage-to-current converter circuit, a first transistor, and a first resistor; wherein
an input terminal of the voltage-to-current converter circuit is electrically connected to the output terminal of the control voltage output circuit, an output terminal of the voltage-to-current converter circuit is electrically connected to a source of the first transistor, a gate of the first transistor is configured to receive a control signal, the control signal being used to control turning on or turning off of the first transistor, a drain of the first transistor is electrically connected to an input terminal of the current mirror, an output terminal of the current mirror is electrically connected to a first terminal of the first resistor and the input terminal of the first driver circuit, and a second terminal of the first resistor is electrically connected to the ground terminal of the first driver circuit;
the voltage-to-current converter circuit is configured to convert the control voltage into a first current, and transmit the first current to the current mirror via the first transistor; and
the current mirror is configured to transmit the first current to the first resistor, such that a voltage across the first resistor is the control voltage, and the control voltage is shifted into the voltage domain.

3. The control circuit according to claim 2, wherein the voltage-to-current converter circuit comprises: a second transistor and a second resistor;
wherein a gate of the second transistor is electrically connected to the output terminal of the control voltage output circuit, a drain of the second transistor is electrically connected to the source of the first transistor, a source of the second transistor is electrically connected to a first terminal of the second resistor, and a second terminal of the second resistor is grounded.

4. The control circuit according to claim 2, wherein the current mirror comprises: a first P-type transistor and a second P-type transistor;
wherein a source of the first P-type transistor and a source of the second P-type transistor are both configured to be connected to a first power supply voltage, a gate of the first P-type transistor, a drain of the first P-type transistor, and a gate of the second P-type transistor are all electrically connected to the drain of the first transistor, and a drain of the second P-type transistor is electrically connected to the first terminal of the first resistor.

5. The control circuit according to claim 1, wherein the level shifter circuit comprises: a charge pump; wherein
an input terminal of the charge pump is electrically connected to the output terminal of the control voltage output circuit, and an output terminal of the charge pump is electrically connected to the input terminal of the first driver circuit; and
the charge pump is configured to, in a first phase, store charge corresponding to the control voltage using a first capacitor in the charge pump, and in a second phase, release the charge stored in the first capacitor, to shift the control voltage into the voltage domain.

6. The control circuit according to claim 5, wherein the level shifter circuit further comprises: a buffer with a unity gain of 1; wherein
a non-inverting input terminal of the buffer is electrically connected to the output terminal of the control voltage output circuit, and an inverting input terminal of the buffer is electrically connected to an output terminal of the buffer and the input terminal of the charge pump; and
the buffer is configured to perform a unity-gain amplification on the control voltage.

7. The control circuit according to claim 5, wherein the charge pump comprises: a first switching transistor, a second switching transistor, a third switching transistor, a fourth switching transistor, and a first capacitor;
wherein a first terminal of the first switching transistor is electrically connected to the output terminal of the control voltage output circuit, a second terminal of the first switching transistor is electrically connected to a first terminal of the third switching transistor, a second terminal of the third switching transistor is electrically connected to the input terminal of the first driver circuit, a first terminal of the second switching transistor is grounded, a second terminal of the second switching transistor is electrically connected to a first terminal of the fourth switching transistor, a second terminal of the fourth switching transistor is electrically connected to the ground terminal of the first driver circuit, an upper plate of the first capacitor is electrically connected between the second terminal of the first switching transistor and the first terminal of the third switching transistor, a lower plate of the first capacitor is electrically connected between the second terminal of the second switching transistor and the first terminal of the fourth switching transistor, and a control terminal of the first switching transistor, a control terminal of the second switching transistor, a control terminal of the third switching transistor, and a control terminal of the fourth switching transistor are all configured to receive a control signal, wherein the control signal is used to control turn-on or turn-off of the first switching transistor, the second switching transistor, the third switching transistor, and fourth switching transistor.

8. The control circuit according to claim 1, wherein the level shifter circuit comprises: a voltage-to-current converter circuit, a current mirror, a first voltage output circuit, and an error amplifier; wherein
a first terminal of the voltage-to-current converter circuit is electrically connected to an input terminal of the current mirror, the input terminal of the first driver circuit, and an output terminal of the error amplifier, a second terminal of the voltage-to-current converter circuit is electrically connected to the ground terminal of the first driver circuit, an output terminal of the current mirror is electrically connected to an input terminal of the first voltage output circuit, an output terminal of the first voltage output circuit is electrically connected to a first input terminal of the error amplifier, and a second input terminal of the error amplifier is electrically connected to the output terminal of the control voltage output circuit;
the voltage-to-current converter circuit is configured to convert the input voltage of the first driver circuit into a first current and transmit the first current to the current mirror;
the current mirror is configured to transmit the first current to the first voltage output circuit;
the first voltage output circuit is configured to, based on the first current, generate a first voltage and transmit the first voltage to the error amplifier, wherein the first voltage is used to represent a variation of the input voltage of the first driver circuit; and
the error amplifier is configured to, based on the control voltage and the first voltage, maintain the input voltage of the first driver circuit stable, to shift the control voltage into the voltage domain.

9. The control circuit according to claim 8, wherein the level shifter circuit further comprises: a sample-and-hold circuit; wherein
an input terminal of the sample-and-hold circuit is electrically connected to the output terminal of the first voltage output circuit, and an output terminal of the sample-and-hold circuit is electrically connected to the first input terminal of the error amplifier; and
the sample-and-hold circuit is configured to, in response to the first power transistor being turned on, sample and hold the first voltage to obtain a second voltage, and transmit the second voltage to the error amplifier, such that the error amplifier, based on the control voltage and the second voltage, maintains the input voltage of the first driver circuit stable.

10. The control circuit according to claim 9, wherein the sample-and-hold circuit comprises: a fifth switching transistor and a third capacitor;
wherein a first terminal of the fifth switching transistor is electrically connected to the output terminal of the first voltage output circuit, a control terminal of the fifth switching transistor is configured to receive a first control signal, the first control signal being used to control turn-on or turn-off of the fifth switching transistor, a second terminal of the fifth switching transistor is electrically connected to the first input terminal of the error amplifier, an upper plate of the third capacitor is electrically connected between the second terminal of the fifth switching transistor and the first input terminal of the error amplifier, and a lower plate of the third capacitor is grounded.

11. The control circuit according to claim 8, wherein the error amplifier comprises: a first differential transconductance amplifier, a first P-type transistor, a second P-type transistor, a first transistor, a second transistor, a third transistor, and a fourth transistor;
wherein a source of the first P-type transistor and a source of the second P-type transistor are both configured to be connected to a first power supply voltage, a gate of the first P-type transistor, a drain of the first P-type transistor, and a gate of the second P-type transistor are all electrically connected to a drain of the first transistor, a source of the first transistor is electrically connected to a drain of the second transistor, a drain of the second P-type transistor is electrically connected to a drain of the third transistor and the first terminal of the voltage-to-current converter circuit, a source of the third transistor is electrically connected to a drain of the fourth transistor, a gate of the fourth transistor is electrically connected to a second output terminal of the first differential transconductance amplifier, a gate of the second transistor is electrically connected to a first output terminal of the first differential transconductance amplifier, a non-inverting input terminal of the first differential transconductance amplifier is electrically connected to the output terminal of the control voltage output circuit, an inverting input terminal of the first differential transconductance amplifier is electrically connected to the output terminal of the first voltage output circuit, a gate of the first transistor and a gate of the third transistor are both configured to receive a second control signal, the second control signal being used to control turn-on or turn-off of the first transistor and the third transistor, and a source of the second transistor and a source of the fourth transistor are both grounded.

12. The control circuit according to claim 8, wherein the first voltage output circuit comprises: a fifth transistor and a first resistor;
wherein a gate of the fifth transistor is electrically connected to the first input terminal of the error amplifier, a drain of the fifth transistor, and the output terminal of the current mirror, a source of the fifth transistor is electrically connected to a first terminal of the first resistor, and a second terminal of the first resistor is grounded.

13. The control circuit according to claim 8, wherein the voltage-to-current converter circuit comprises: a sixth transistor and a second resistor;
wherein a gate of the sixth transistor is electrically connected to the input terminal of the first driver circuit and the output terminal of the error amplifier, a drain of the sixth transistor is electrically connected to the input terminal of the current mirror, a source of the sixth transistor is electrically connected to a first terminal of the second resistor, and a second terminal of the second resistor is electrically connected to the ground terminal of the first driver circuit.

14. The control circuit according to claim 1, wherein the control voltage output circuit comprises: a second differential transconductance amplifier, a current source, an N-type transistor, and a second capacitor; wherein
a non-inverting input terminal of the second differential transconductance amplifier is configured to receive the reference voltage, an inverting input terminal of the second differential transconductance amplifier is configured to receive the feedback voltage, an output terminal of the second differential transconductance amplifier is electrically connected to a gate of the N-type transistor, an input terminal of the current source is configured to be connected to a second power supply voltage, an output terminal of the current source is electrically connected to a drain of the N-type transistor, an upper plate of the second capacitor is electrically connected between the output terminal of the current source and the drain of the N-type transistor, the upper plate of the second capacitor is further electrically connected to the input terminal of the level shifter circuit, and a lower plate of the second capacitor and a source of the N-type transistor are both grounded; and
the second differential transconductance amplifier is configured to, based on the reference voltage and the feedback voltage, control the N-type transistor to be turned on, to convert a voltage difference between the reference voltage and the feedback voltage into a current, such that the control voltage is generated.

15. The control circuit according to claim 1, wherein the first driver circuit comprises: a seventh transistor, an eighth transistor, a ninth transistor, and a capacitor;
wherein a source of the seventh transistor is configured to be connected to a first power supply voltage, a drain of the seventh transistor is electrically connected to a drain of the eighth transistor, a gate of the eighth transistor is electrically connected to the output terminal of the level shifter circuit, a source of the eighth transistor is electrically connected to a drain of the ninth transistor, an upper plate of the capacitor is electrically connected between the gate of the eighth transistor and the output terminal of the level shifter circuit, and a lower plate of the capacitor and a source of the ninth transistor are both electrically connected to the source of the first power transistor.

16. A switched-capacitor converter, comprising: a first group of power transistors, a second group of power transistors, a first driver circuit, a second driver circuit, a plurality of flying capacitors, and a control circuit; wherein the control circuit comprises: a control voltage output circuit and a level shifter circuit; wherein
a first input terminal of the control voltage output circuit is configured to receive a reference voltage, a second input terminal of the control voltage output circuit is configured to receive a feedback voltage, the feedback voltage being used to represent a conversion of an input current or an output current or an output voltage of the switched-capacitor converter, an output terminal of the control voltage output circuit is electrically connected to an input terminal of the level shifter circuit, an output terminal of the level shifter circuit is electrically connected to an input terminal of the first driver circuit, an output terminal of the first driver circuit is electrically connected to a gate of the first power transistor, and a ground terminal of the first driver circuit is electrically connected to a source of the first power transistor;
the control voltage output circuit is configured to, based on the reference voltage and the feedback voltage, acquire a control voltage and transmit the control voltage to the level shifter circuit, wherein the control voltage is used to control an input voltage of the first driver circuit;
the level shifter circuit is configured to shift the control voltage into a voltage domain of the first driver circuit, such that the control circuit controls a turn-on voltage of the first power transistor using the control voltage, to control the input current or the output current or the output voltage;
the first driver circuit is configured to drive the first group of power transistors to switch between a turned-on state and a turned-off state;
the second driver circuit is configured to drive the second group of power transistors to switch between a turned-on state and a turned-off state;
the first group of power transistors and the second group of power transistors are configured to, during switching between the turned-on state and the turned-off state, control the plurality of flying capacitors to switch between charging and discharging, to convert an input voltage of the switched-capacitor converter into a plurality of output voltages; and
the control circuit is configured to control a turn-on voltage of the first group of power transistors, to control the input current or the output current or the output voltage of the switched-capacitor converter.

17. The switched-capacitor converter according to claim 16, wherein
the plurality of flying capacitors comprises: a first flying capacitor, a second flying capacitor, a third flying capacitor, and a fourth flying capacitor; wherein
the first group of power transistors comprise: a third power transistor and a fourth power transistor; and
the second group of power transistors comprises: a fifth power transistor, a sixth power transistor, a seventh power transistor, an eighth power transistor, a ninth power transistor, a tenth power transistor, an eleventh power transistor, a twelfth power transistor, a thirteenth power transistor, a fourteenth power transistor, a fifteenth power transistor, a sixteenth power transistor, a seventeenth power transistor, and an eighteenth power transistor;
wherein
a drain of the third power transistor and a drain of the fourth power transistor are both configured to receive the input voltage of the switched-capacitor converter, a source of the fourth power transistor is electrically connected to a drain of the eighth power transistor, a source of the eighth power transistor is electrically connected to a drain of the twelfth power transistor, a source of the third power transistor is electrically connected to a drain of the seventh power transistor, a source of the seventh power transistor is electrically connected to a drain of the eleventh power transistor, a source of the fifth power transistor and a source of the sixth power transistor are both grounded, a drain of the fifth power transistor is electrically connected to a source of the ninth power transistor, a drain of the sixth power transistor is electrically connected to a source of the tenth power transistor, a first output terminal of the switched-capacitor converter is electrically connected between the source of the eighth power transistor and the drain of the twelfth power transistor, and the first output terminal of the switched-capacitor converter is further electrically connected between the source of the seventh power transistor and the drain of the eleventh power transistor;
a first plate of the first flying capacitor is electrically connected between the source of the fourth power transistor and the drain of the eighth power transistor, a second plate of the first flying capacitor is electrically connected between the drain of the fifth power transistor and the source of the ninth power transistor, a first plate of the second flying capacitor is electrically connected between the source of the fourth power transistor and the drain of the seventh power transistor, and a second plate of the second flying capacitor is electrically connected between the drain of the sixth power transistor and the source of the tenth power transistor;
a drain of the ninth power transistor is electrically connected to a first plate of the third flying capacitor, a second plate of the third flying capacitor is electrically connected to a drain of the seventeenth power transistor, a source of the seventeenth power transistor is grounded, a source of the eleventh power transistor and a drain of the thirteenth power transistor are both electrically connected between the drain of the ninth power transistor and the first plate of the third flying capacitor, a source of the fifteenth power transistor is electrically connected between the second plate of the third flying capacitor and the drain of the seventeenth power transistor, and a source of the thirteenth power transistor and a drain of the fifteenth power transistor are both electrically connected to a second output terminal of the switched-capacitor converter;
a drain of the tenth power transistor is electrically connected to a first plate of the fourth flying capacitor, a second plate of the fourth flying capacitor is electrically connected to a drain of the eighteenth power transistor, a source of the eighteenth power transistor is grounded, a source of the twelfth power transistor and a drain of the fourteenth power transistor are both electrically connected between the drain of the tenth power transistor and the first plate of the fourth flying capacitor, a source of the sixteenth power transistor is electrically connected between the second plate of the fourth flying capacitor and the drain of the eighteenth power transistor, and a source of the fourteenth power transistor and a drain of the sixteenth power transistor are both electrically connected to the second output terminal of the switched-capacitor converter; and
gates of the third power transistor and the fourth power transistor are both electrically connected to an output terminal of the first driver circuit, and a gate of each power transistor of the second group of power transistors is electrically connected to the second driver circuit.

18. A chip, comprising: a control circuit, applied in a switched-capacitor converter, the switched-capacitor converter comprising: a first power transistor and a first driver circuit, and the control circuit comprising: a control voltage output circuit and a level shifter circuit; wherein
a first input terminal of the control voltage output circuit is configured to receive a reference voltage, a second input terminal of the control voltage output circuit is configured to receive a feedback voltage, the feedback voltage being used to represent a conversion of an input current or an output current or an output voltage of the switched-capacitor converter, an output terminal of the control voltage output circuit is electrically connected to an input terminal of the level shifter circuit, an output terminal of the level shifter circuit is electrically connected to an input terminal of the first driver circuit, an output terminal of the first driver circuit is electrically connected to a gate of the first power transistor, and a ground terminal of the first driver circuit is electrically connected to a source of the first power transistor;
the control voltage output circuit is configured to, based on the reference voltage and the feedback voltage, acquire a control voltage and transmit the control voltage to the level shifter circuit, wherein the control voltage is used to control an input voltage of the first driver circuit; and
the level shifter circuit is configured to shift the control voltage into a voltage domain of the first driver circuit, such that the control circuit controls a turn-on voltage of the first power transistor using the control voltage, to control the input current or the output current or the output voltage.

19. An electronic device, comprising: a switched-capacitor converter, comprising: a first group of power transistors, a second group of power transistors, a first driver circuit, a second driver circuit, a plurality of flying capacitors, and a control circuit; wherein the control circuit comprises: a control voltage output circuit and a level shifter circuit; wherein
a first input terminal of the control voltage output circuit is configured to receive a reference voltage, a second input terminal of the control voltage output circuit is configured to receive a feedback voltage, the feedback voltage being used to represent a conversion of an input current or an output current or an output voltage of the switched-capacitor converter, an output terminal of the control voltage output circuit is electrically connected to an input terminal of the level shifter circuit, an output terminal of the level shifter circuit is electrically connected to an input terminal of the first driver circuit, an output terminal of the first driver circuit is electrically connected to a gate of the first power transistor, and a ground terminal of the first driver circuit is electrically connected to a source of the first power transistor;
the control voltage output circuit is configured to, based on the reference voltage and the feedback voltage, acquire a control voltage and transmit the control voltage to the level shifter circuit, wherein the control voltage is used to control an input voltage of the first driver circuit;
the level shifter circuit is configured to shift the control voltage into a voltage domain of the first driver circuit, such that the control circuit controls a turn-on voltage of the first power transistor using the control voltage, to control the input current or the output current or the output voltage;
the first driver circuit is configured to drive the first group of power transistors to switch between a turned-on state and a turned-off state;
the second driver circuit is configured to drive the second group of power transistors to switch between a turned-on state and a turned-off state;
the first group of power transistors and the second group of power transistors are configured to, during switching between the turned-on state and the turned-off state, control the plurality of flying capacitors to switch between charging and discharging, to convert an input voltage of the switched-capacitor converter into a plurality of output voltages; and
the control circuit is configured to control a turn-on voltage of the first group of power transistors, to control the input current or the output current or the output voltage of the switched-capacitor converter.

20. The electronic device according to claim 19, wherein
the plurality of flying capacitors comprises: a first flying capacitor, a second flying capacitor, a third flying capacitor, and a fourth flying capacitor; wherein the first group of power transistors comprise: a third power transistor and a fourth power transistor; and
the second group of power transistors comprises: a fifth power transistor, a sixth power transistor, a seventh power transistor, an eighth power transistor, a ninth power transistor, a tenth power transistor, an eleventh power transistor, a twelfth power transistor, a thirteenth power transistor, a fourteenth power transistor, a fifteenth power transistor, a sixteenth power transistor, a seventeenth power transistor, and an eighteenth power transistor;
wherein
a drain of the third power transistor and a drain of the fourth power transistor are both configured to receive the input voltage of the switched-capacitor converter, a source of the fourth power transistor is electrically connected to a drain of the eighth power transistor, a source of the eighth power transistor is electrically connected to a drain of the twelfth power transistor, a source of the third power transistor is electrically connected to a drain of the seventh power transistor, a source of the seventh power transistor is electrically connected to a drain of the eleventh power transistor, a source of the fifth power transistor and a source of the sixth power transistor are both grounded, a drain of the fifth power transistor is electrically connected to a source of the ninth power transistor, a drain of the sixth power transistor is electrically connected to a source of the tenth power transistor, a first output terminal of the switched-capacitor converter is electrically connected between the source of the eighth power transistor and the drain of the twelfth power transistor, and the first output terminal of the switched-capacitor converter is further electrically connected between the source of the seventh power transistor and the drain of the eleventh power transistor;
a first plate of the first flying capacitor is electrically connected between the source of the fourth power transistor and the drain of the eighth power transistor, a second plate of the first flying capacitor is electrically connected between the drain of the fifth power transistor and the source of the ninth power transistor, a first plate of the second flying capacitor is electrically connected between the source of the fourth power transistor and the drain of the seventh power transistor, and a second plate of the second flying capacitor is electrically connected between the drain of the sixth power transistor and the source of the tenth power transistor;
a drain of the ninth power transistor is electrically connected to a first plate of the third flying capacitor, a second plate of the third flying capacitor is electrically connected to a drain of the seventeenth power transistor, a source of the seventeenth power transistor is grounded, a source of the eleventh power transistor and a drain of the thirteenth power transistor are both electrically connected between the drain of the ninth power transistor and the first plate of the third flying capacitor, a source of the fifteenth power transistor is electrically connected between the second plate of the third flying capacitor and the drain of the seventeenth power transistor, and a source of the thirteenth power transistor and a drain of the fifteenth power transistor are both electrically connected to a second output terminal of the switched-capacitor converter;
a drain of the tenth power transistor is electrically connected to a first plate of the fourth flying capacitor, a second plate of the fourth flying capacitor is electrically connected to a drain of the eighteenth power transistor, a source of the eighteenth power transistor is grounded, a source of the twelfth power transistor and a drain of the fourteenth power transistor are both electrically connected between the drain of the tenth power transistor and the first plate of the fourth flying capacitor, a source of the sixteenth power transistor is electrically connected between the second plate of the fourth flying capacitor and the drain of the eighteenth power transistor, and a source of the fourteenth power transistor and a drain of the sixteenth power transistor are both electrically connected to the second output terminal of the switched-capacitor converter; and
gates of the third power transistor and the fourth power transistor are both electrically connected to an output terminal of the first driver circuit, and a gate of each power transistor of the second group of power transistors is electrically connected to the second driver circuit.
